(19) United States
(12) Patent Application Publication
(10) Pub. No.: US 2002/0089264 A1
(43) Pub. Date: Jul. 11, 2002

(54) HERMETICALLY SEALED DUAL-BAND SURFACE ACOUSTIC WAVE CIRCUIT MODULE

(76) Inventor: James E. Flowers, Dallas, TX (US)

Correspondence Address: David H. Hitt, Hitt Gaines & Boisbrun, P.C., P.O. Box 832570, Richardson, TX, 75083, US

(21) Appl. No.: 09/755,991

(22) Filed: Jan. 5, 2001

(51) Int. Cl. H01L 41/04

(52) U.S. Cl. 310/348

(57) ABSTRACT

A module that contains multiple surface acoustic wave (SAW) circuits and a method of manufacturing the module. In one embodiment, the module includes: (1) a hermetically-sealable shell having first and second terminal sets, (2) a first SAW circuit, located within the shell and couplable to the first terminal set, that filters signals in a first band of communications frequencies, and (3) a second SAW circuit, located within the shell and couplable to the second terminal set, that filters signals in a second band of communications frequencies.

### TECHNICAL FIELD OF THE INVENTION

The present invention is directed, in general, to surface acoustic wave (SAW) filters and, more specifically, to a module having dual-band SAW circuits and a method of manufacturing such module.

### BACKGROUND OF THE INVENTION

Surface acoustic wave (SAW) devices for use in electronic signal processing have been advantageously adopted by the electronics industry. Such SAW devices have several advantages over more conventional technologies. They can be designed to provide complex signal processing in a single unit, and they also offer an additional benefit from their ability to be mass produced using semiconductor microfabrication techniques. These techniques lead to lower-cost devices having only small operating characteristic variations from unit to unit. Since SAW devices may be implemented in small, rugged, light-weight and power-efficient modules, they find many important applications especially in mobile, wireless and spaceborne communication systems. Such communication systems typically operate over a wide range of frequencies from about 10 megahertz to about two gigahertz. The specific signal processing capabilities and frequency range of SAW devices may be determined to allow SAW devices to perform several roles in electronic systems.

An important feature of the SAW device is its geometry, which incorporates two metal patterns having interdigitated conductive lines or traces. Such interdigitated metal structures are formed on a piezoelectric substrate and act as input and output signal paths when an AC signal voltage is applied to one of the metal structures. This AC voltage induces a surface acoustic wave in the underlying substrate wherein the acoustic wave propagates to the output structure. The interdigitated metal lines of the signal receiving portion detects the acoustic wave and converts it into a filtered electrical output signal. SAW devices, operating in the Rayleigh wave mode, can generally be designed to provide bandpass filters that achieve responses that would otherwise require several hundred inductors and capacitors in conventional LC filter designs. Proper operation and containment of the acoustic waves require precise construction of both the central and outlying regions.

Currently, multiple SAW devices having various frequencies are being implemented within a single device, such as a conventional dual mode cellular phone. Combining at least two SAW devices having varying frequencies within a single device has become well accepted, unfortunately, each SAW device must be independently packaged, requiring valuable space in today's technologies. In addition, independently packaging the SAW devices is expensive and provides an additional element from which reliability issues may arise.

Accordingly, what is needed in the art is a method of packaging the multiple SAW devices that does not experience the problems associated with the prior art.

### SUMMARY OF THE INVENTION

To address the above-discussed deficiencies of the prior art, the present invention provides a module that contains multiple SAW circuits and a method of manufacturing the module. In one embodiment, the module includes: (1) a hermetically-sealable shell having first and second terminal sets, (2) a first SAW circuit, located within the shell and couplable to the first terminal set, that filters signals in a first band of communications frequencies, and (3) a second SAW circuit, located within the shell and couplable to the second terminal set, that filters signals in a second band of communications frequencies.

The present invention therefore introduces the broad concept of unifying multiple SAW circuits for corresponding multiple communications bands in a single modular package, so the module can be employed space-efficiently as a unit in applications such as dual-band wireless telephones.

In one embodiment of the present invention, the first band of communications frequencies comprises a frequency between 800 and 900 megahertz. In another embodiment of the present invention, the second band of communications frequencies comprises a frequency between 1800 and 1900 megahertz. In an embodiment to be illustrated and described, a single module contains SAW circuits for both such bands and is particularly suited for use in dual-band analog and PCS telephones.

In one embodiment of the present invention, the shell comprises a common base that supports the first and second SAW circuits. In one embodiment to be illustrated and described, the common base includes ceramic. However, the common base may include silicon, a piezoelectric material, or any other suitable material for providing mechanical support, a substrate for formation of integrated circuitry, or both.

In one embodiment of the present invention, the module further includes a lid coupled to the shell to form a hermetic enclosure that surrounds the first and second SAW circuits. As with the common base, the lid may include ceramic. However, the lid may include silicon, a piezoelectric material, or any other suitable material for sealing the module, providing a substrate for formation of integrated circuitry, or both. The hermetic enclosure advantageously isolates the SAW circuits from environmental contaminants and damage that would harm their operation.

In one embodiment of the present invention, the first and second SAW circuits are located on a common piezoelectric substrate (single die) . Of course, the first and second SAW circuits may be located on separate substrates.

In one embodiment of the present invention, the module further comprises a crosstalk shield located between the first and second SAW circuits. Of course, the first and second SAW circuits may be located on separate piezoelectric substrates.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of a module constructed according to the principles of the present invention;

FIG. 2 illustrates a diagram of an embodiment of a module constructed according to the principles of the present invention; and

FIG. 3 illustrates a sectioned view of a module showing an embodiment of the present invention.

### DETAILED DESCRIPTION

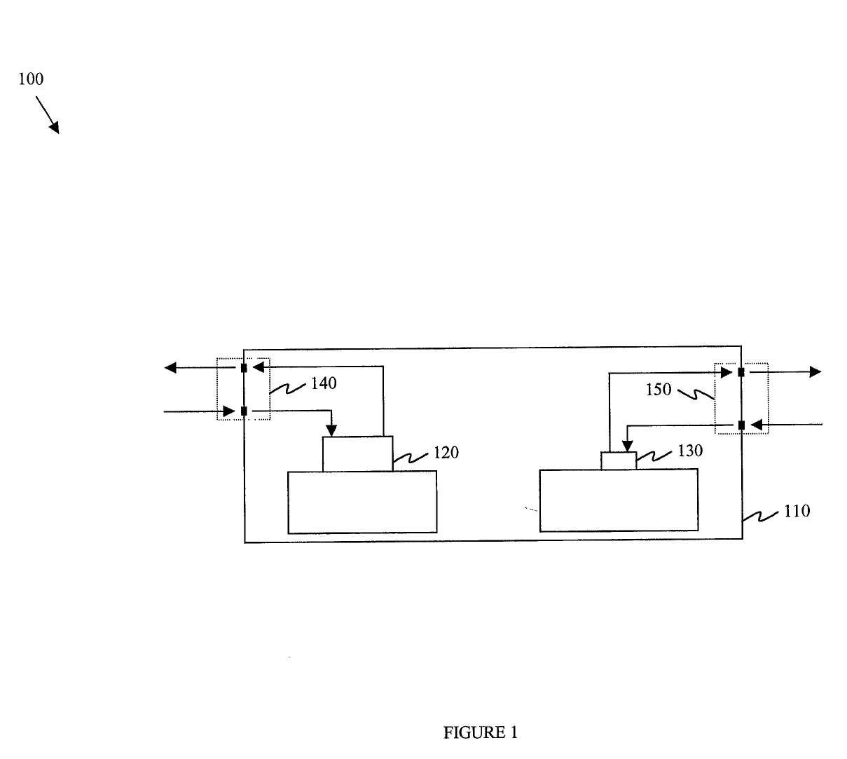

Referring initially to FIG. 1, illustrated is a block diagram of a module 100 constructed according to the principles of the present invention. The module 100 includes a shell 110, a first surface acoustic wave (SAW) circuit 120, and a second SAW circuit 130. The shell 110 is a hermetically-sealable shell that surrounds the first and second SAW circuits 120, 130. The hermetically-sealable shell advantageously isolates the SAW circuits 120, 130 from environmental contaminants and damage that might harm their operation. The shell 110 further includes first and second terminal sets 140, 150 respectively, located therein.

In the illustrated embodiment, the first SAW circuit 120 is located within the shell 110 and is couplable to the first terminal set 140. The first saw circuit 120 is configured to filter signals in a first band of communications frequencies. For example, in an exemplary embodiment, the first saw circuit may be designed to filter signals in a band of frequencies ranging from about 800 to about 900 megahertz. Such a SAW circuit is similar to a SAW circuit that could be used in a traditional analog communications device.

As previously mentioned, also located within the shell 110 is the second SAW circuit 130. As illustrated, the second SAW circuit 130 is couplable to the second terminal set 150. The second SAW circuit 130 is configured to filter signals in a second band of communications frequencies. The second band of communications frequencies, in an alternative embodiment, may comprise frequencies ranging from about 1800 to about 1900 megahertz. Such frequencies may generally be associated with filters used in conjunction with PCS devices. While only two SAW devices were discussed above as being included within the shell 110, one having skill in the art understands that more than two SAW devices may be located within the shell 110, and thus, are within the scope of the present invention. Likewise, the range of frequencies that may be filtered using the SAW circuits may vary from the ranges disclosed above, without departing from the scope of the present invention.

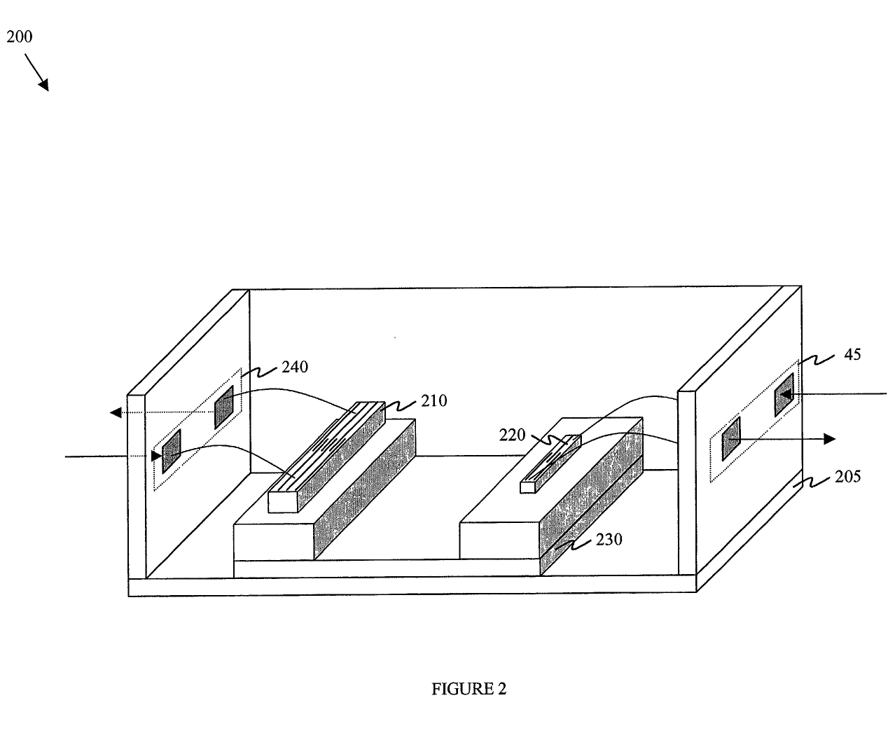

Turning now to FIG. 2, illustrated is a diagram of an embodiment of a module 200 constructed according to the principles of the present invention. The module 200 includes a hermetically-sealable shell 205 having a first SAW circuit 210 and a second SAW circuit 220 located therein. As illustrated in FIG. 2, the shell 205 includes a common base 230, such as a ceramic common base, that supports the first and second SAW circuits 210, 220. It should be noted, however, the common base 230 may include silicon, a piezoelectric material, or any other suitable material for providing mechanical support, a substrate for formation of integrated circuitry, or both. The common base 230 may be, as illustrated, a separate base formed over a lower portion of the shell 205, or in an alternative embodiment, may be the lower portion of the shell 205. Likewise, it should be noted that the common base 230 may also contain electrical contacts (not shown), that provide interconnection paths from first and second terminal sets 240, 245 to the first and second SAW circuits 210, 220, respectively.

In the embodiment illustrated in FIG. 2, the module 200 does not yet have a lid coupled to the shell 205. In certain instances it is believed that the module 200, without having the lid formed thereon, may be sold to a vendor, wherein the vendor forms other circuits within the shell. Subsequent to forming other circuits within the shell, the lid could be formed over the shell to create a hermatic enclosure that surrounds the first and second SAW circuits 210, 220 and the additional circuits. One advantageous embodiment of the present invention provides a power amplifier as the additional circuit, however, one skilled in the art understands that other additional circuits could be placed within the shell 205 without departing from the scope of the present invention.

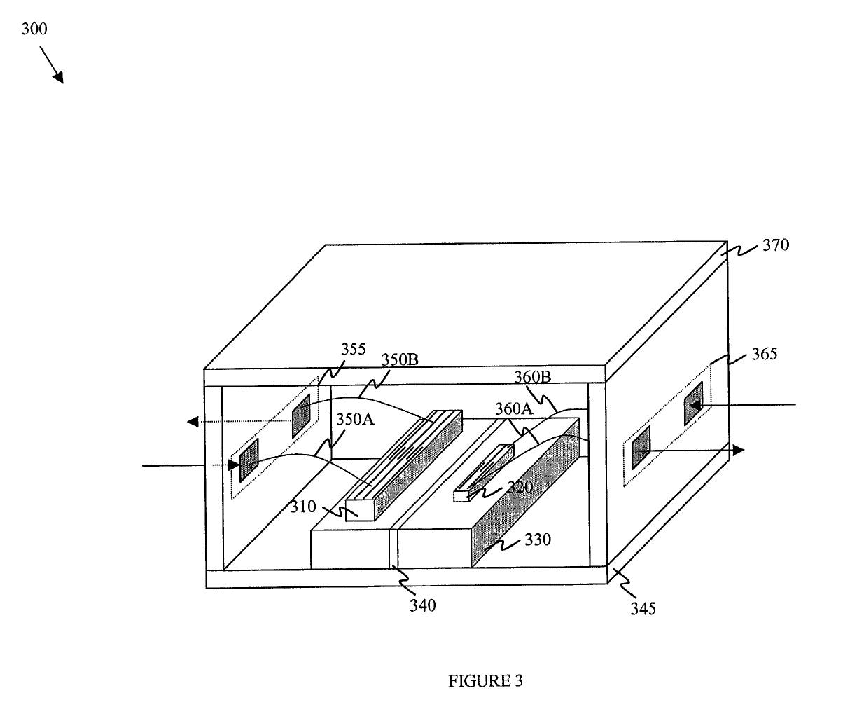

Turning now to FIG. 3, illustrated is a sectioned view of a module 300 showing an embodiment of the present invention. The module 300 includes a first SAW circuit 310 and a second SAW circuit 320 formed over a common piezoelectric substrate 330, and within a shell 305. As illustrated, the common piezoelectric substrate 330 includes a crosstalk shield 340 located therein, and between the first and second SAW circuits 310, 320. The crosstalk shield 340 provides a signal isolation barrier between the first and second SAW circuits 310, 320. The crosstalk shield 340 prevents signals within each of the first and second SAW circuits 310, 320 from interfering with the other since they are in close proximity and share the common piezoelectric substrate 330. In an exemplary embodiment, the signal isolation is achieved by connecting the crosstalk shield 340 to ground.

The module 300 further illustrates a method of manufacturing an embodiment of a circuit module constructed according to the principles of the present invention. First, a ceramic common base 345 is provided. Then, the first and second SAW circuits 310, 320 are placed on the ceramic common base 345. In the illustrated embodiment of FIG. 3, first and second SAW circuits 310, 320 are formed on the common piezoelectric substrate 330, however, in an alternative embodiment, the first and second SAW circuits 310, 320 may be formed on separate piezoelectric substrates, as illustrated in FIG. 2.

Next, first and second bond wires 350A, 350B are connected between the first SAW circuit 310 and a first terminal set 355, and third and fourth bond wires 360A, 360B are connected between the second SAW circuit 320 and a second terminal set 365. Optionally, at this point, an additional circuit could be included within the shell 305. Finally, the ceramic lid enclosure 370 is placed in position on the shell 305 during appropriate ambient conditions, and the module 300 is hermetically sealed. The lid 370, similar to the base 345, may comprise ceramic, silicon, a piezoelectric material, or any other suitable material for providing mechanical support, a substrate for formation of integrated circuitry, or both.

In summary, the present invention introduces the novel concept of a module including first and second SAW circuits within a common hermetically-sealable shell, wherein the first and second SAW circuits have first and second bands of communications frequencies. Since multiple SAW circuits may be included within a single hermetically-sealable shell, many of the space, cost and reliability issues associated with the prior art devices are substantially eliminated.

Although the present invention has been described in detail, those skilled in the art should understand that they can make various changes, substitutions and alterations herein without departing from the spirit and scope of the invention in its broadest form.

What is claimed is:

1. A module, comprising:
a hermetically-sealable shell having first and second terminal sets;
a first surface acoustic wave (SAW) circuit, located within said shell and couplable to said first terminal set, that filters signals in a first band of communications frequencies; and
a second SAW circuit, located within said shell and couplable to said second terminal set, that filters signals in a second band of communications frequencies.

2. The module as recited in claim 1 wherein said first band of communications frequencies comprises a frequency between 800 and 900 megahertz.

3. The module as recited in claim 1 wherein said second band of communications frequencies comprises a frequency between 1800 and 1900 megahertz.

4. The module as recited in claim 1 wherein said shell comprises a common base that supports said first and second SAW circuits.

5. The module as recited in claim 1 further comprising a lid coupled to said shell to form a hermetic enclosure that surrounds said first and second SAW circuits.

6. The module as recited in claim 1 wherein said first and second SAW circuits are located on a common piezoelectric substrate.

7. The module as recited in claim 6 further comprising a crosstalk shield located between said first and second SAW circuits.

8. A method of manufacturing a circuit module, comprising:
providing a hermetically-sealable shell having first and second terminal sets;
placing a first surface acoustic wave (SAW) circuit in said shell, said first SAW circuit capable of filtering signals in a first band of communications frequencies;
coupling said first SAW circuit to said first terminal set;
placing a second SAW circuit in said shell, said second SAW circuit capable of filtering signals in a second band of communications frequencies;
coupling said second SAW circuit to said second terminal set; and
placing a lid on said shell to form an enclosure that surrounds said first and second SAW circuits.

9. The method as recited in claim 8 wherein said first band of communications frequencies comprises a frequency between 800 and 900 megahertz.

10. The method as recited in claim 8 wherein said second band of communications frequencies comprises a frequency between 1800 and 1900 megahertz.

11. The method as recited in claim 8 wherein said shell comprises a common base that supports said first and second SAW circuits.

12. The method as recited in claim 8 wherein said enclosure is hermetic.

13. The method as recited in claim 8 wherein said first and second SAW circuits are located on a common piezoelectric substrate.

14. The method as recited in claim 13 further comprising forming a crosstalk shield between said first and second SAW circuits.

15. A module, comprising:
a hermetically-sealable shell having first and second terminal sets;
a first surface acoustic wave (SAW) circuit, located within said shell and couplable to said first terminal set, that filters signals in a first band of communications frequencies;
a second SAW circuit, located within said shell and couplable to said second terminal set, that filters signals in a second band of communications frequencies; and
a lid coupled to said shell and forming an enclosure that surrounds said first and second SAW circuits.

16. The module as recited in claim 15 wherein said first band of communications frequencies comprises a frequency between 800 and 900 megahertz.

17. The module as recited in claim 15 wherein said second band of communications frequencies comprises a frequency between 1800 and 1900 megahertz.

18. The module as recited in claim 15 wherein said shell comprises a common base that supports said first and second SAW circuits.

19. The module as recited in claim 15 wherein said enclosure is hermetic.

20. The module as recited in claim 15 wherein said first and second SAW circuits are located on a common piezoelectric substrate.

21. The module as recited in claim 20 wherein a crosstalk shield is located between said first and second SAW circuits.
